(19) United States
(12) Patent Application Publication
(10) Pub. No.: US 2024/0250706 A1
(43) Pub. Date: Jul. 25, 2024

(54) SELF-INTERFERENCE CANCELATION APPARATUS IN PIEZOELECTRIC SEMICONDUCTOR PLATFORMS

(71) Applicant: University of Central Florida Research Foundation, Inc., Orlando, FL (US)

(72) Inventors: Hakhamanesh Mansoorzare, Orlando, FL (US); Reza Abdolvand, Orlando, FL (US)

(21) Appl. No.: 18/514,389

(22) Filed: Nov. 20, 2023

Related U.S. Application Data
(60) Provisional application No. 63/440,238, filed on Jan. 20, 2023.

(51) Int. Cl. H04B 1/04; H03H 9/42; H04B 1/10

(52) U.S. Cl. CPC H04B 1/0475; H03H 9/423; H04B 1/10

(57) ABSTRACT

Systems and devices for a self-interference cancelation scheme that allows for large numbers of delays while maintaining a small size and area. The main components of this scheme include AE delay line arrays (for re-constructing the interference to be subtracted); AE circulators (for providing isolation between the transmitter-to-antenna and antenna-to-receiver paths); and AE couplers (for tapping the signal from the transmit chain to the delay lines). Together, a fully micro-acoustic interference cancelation module is realized in thin-film piezoelectric-semiconductor heterostructures, which are usable in cellular communication devices, base stations, wireless communication modules, and similar transmission/reception systems.

### CROSS-REFERENCE TO RELATED APPLICATIONS

This nonprovisional application is a continuation of and claims priority to provisional application No. 63/440,238, titled “Self-interference cancelation apparatus in piezoelectric semiconductor platforms,” filed on Jan. 20, 2023 by the same inventors.

### FEDERALLY SPONSORED RESEARCH OR DEVELOPMENT

This invention was made with government support under Grant No. 2122670 awarded by the National Science Foundation. The government has certain rights in the invention.

### BACKGROUND OF THE INVENTION

### 1. Field of the Invention

This invention relates, generally, to self-interference cancelations in wireless connectivity systems. More specifically, it relates to a self-interference cancelation apparatus in piezoelectric semiconductor platforms that combines analog and digital techniques to provide miniaturized delay-attenuator functionality for chip-scale implementations thereof.

### 2. Brief Description of the Prior Art

The wireless communication industry is currently facing challenges in the form of limited availability of the frequency spectrum for supporting increased connectivity and data, as well as limited power and size for managing the frequency spectrum. A major problem is the limited interference cancelation schemes that are currently available in the analog domain. In practice, full-duplex radio—which theoretically doubles the available frequency spectrum and is highly desired—requires more than 100 dB interference cancelation, roughly half of which needs to be implemented in the analog domain.

The more stringent frequency band allocation and full-duplex wireless communication have made self-interference cancelation critical, since reception and transmission occur at close bands or at the same time on the same channel. To successfully cancel the interference due to the transmitting module or multi-path reflections, the interference must be correctly estimated and subtracted in the signal path prior to desensitizing the receiver. A viable solution to this problem has been previously proposed by summing weighted and delayed copies of the original signal to mimic the interference. This solution has been implemented in the electromagnetic domain using a combination of microstrip delay lines and variable attenuators. However, adopting this solution in the sub-6 GHz frequency, where the frequency spectrum is extremely congested and the electromagnetic wavelength is in centimeters scale, requires a prohibitively large amount of area. This is especially limiting, since the higher the number of delayed copies, the better the cancelation.

The solutions that are currently available for self-interference cancelation rely on transmission lines in the electromagnetic domain for realizing delay, which is prohibitively large. In order to miniaturize this scheme, acoustic delay lines can be used; however, they are passive and in need of additional circuitry for dynamic modulation of their amplitude/phase, which ultimately increases the module size and complexity.

Accordingly, what is needed is a miniaturized version of a self-interference cancelation scheme that allows for large numbers of delays while maintaining a small size and area. However, in view of the art considered as a whole at the time the present invention was made, it was not obvious to those of ordinary skill in the field of this invention how the shortcomings of the prior art could be overcome.

All referenced publications are incorporated herein by reference in their entirety. Furthermore, where a definition or use of a term in a reference, which is incorporated by reference herein, is inconsistent or contrary to the definition of that term provided herein, the definition of that term provided herein applies and the definition of that term in the reference does not apply.

While certain aspects of conventional technologies have been discussed to facilitate disclosure of the invention, Applicant in no way disclaims these technical aspects, and it is contemplated that the claimed invention may encompass one or more of the conventional technical aspects discussed herein.

The present invention may address one or more of the problems and deficiencies of the prior art discussed above. However, it is contemplated that the invention may prove useful in addressing other problems and deficiencies in a number of technical areas. Therefore, the claimed invention should not necessarily be construed as limited to addressing any of the particular problems or deficiencies discussed herein.

In this specification, where a document, act or item of knowledge is referred to or discussed, this reference or discussion is not an admission that the document, act or item of knowledge or any combination thereof was at the priority date, publicly available, known to the public, part of common general knowledge, or otherwise constitutes prior art under the applicable statutory provisions; or is known to be relevant to an attempt to solve any problem with which this specification is concerned.

### BRIEF SUMMARY OF THE INVENTION

The long-standing but heretofore unfulfilled need for a self-interference cancelation scheme is now met by a new, useful, and nonobvious invention.

The novel self-interference cancelation scheme includes an acoustoelectric delay line array that is configured to receive each of a plurality of incoming electromagnetic radio frequency signals. The acoustoelectric delay line array includes one or more individual delay lines. Each delay line includes a first transducer, a propagation delay section, a second transducer, and a plurality of electrodes. The first transducer is configured to convert each of the plurality of incoming electromagnetic radio frequency signals into a mechanical/acoustic signal via piezoelectricity. The propagation delay section is configured to provide a time delay as each mechanical/acoustic signal propagates therethrough. The plurality of electrodes are configured to induce a lateral and/or vertical electric field within a portion of at least one of the individual delay lines, such that an amplitude and a phase of the mechanical/acoustic signal is tuned. The acoustoelectric delay line array replicates an interfering signal at a receiver chain by combining weighted and delayed copies of an interfering signal at a transmitter chain.

In an embodiment, the scheme includes an acoustoelectric coupler electrically coupled to the acoustoelectric delay line array. The acoustoelectric coupler includes at least one input transducer, a coupling section, at least two output transducers, and a plurality of electrodes. The at least one input transducer is configured to convert each of the plurality of incoming electromagnetic radio frequency signals into a mechanical/acoustic signal via piezoelectricity. The coupling section is configured to direct a propagation of a portion of each mechanical/acoustic signal therethrough. The at least two output transducers are each configured to convert each directed mechanical/acoustic signal into a transmitted electrical domain signal. The plurality of electrodes are configured to induce a lateral and/or vertical electric field within a portion of a propagation path of each mechanical/acoustic signal. In an embodiment, the acoustoelectric coupler is configured to initially receive each of the plurality of incoming electromagnetic radio frequency signals and transmit a portion of each of the plurality of incoming electromagnetic radio frequency signals to the acoustoelectric delay line array. Embodiments of the acoustoelectric coupler include one or more multistrip couplers.

In an embodiment, the scheme includes an acoustoelectric circulator electrically coupled to the acoustoelectric delay line array. An embodiment of the acoustoelectric circulator includes at least three transducers, a propagation section, and a plurality of electrodes. The least three transducers are configured to convert each of the plurality of incoming electromagnetic radio frequency signals into a mechanical/acoustic signal via piezoelectricity. The propagation section is disposed in between each of the at least three transducers, and is configured for nonreciprocal propagation of each mechanical/acoustic signal therethrough. The plurality of electrodes are configured to induce a lateral and/or vertical electric field within a portion of a propagation path of each mechanical/acoustic signal. In an embodiment, the at least three transducers are configured to convert each of the plurality of incoming mechanical/acoustic signals into one or more outgoing electromagnetic radio frequency signals via piezoelectricity. In an embodiment, the acoustoelectric circulator is configured to further enhance cancelation provided by the acoustoelectric delay line array implemented in a shared-antenna radio.

An embodiment of the acoustoelectric circulator includes a plurality of interconnected acoustoelectric isolators and a plurality of power dividers. Each power divider is disposed between adjacent acoustoelectric isolators. The plurality of interconnected acoustoelectric isolators guide signals in only a single direction. In an embodiment, the plurality of interconnected acoustoelectric isolators are interconnected in a delta topology.

In an embodiment, the scheme includes a waveguide comprised of a hybrid piezoelectric-semiconductor substrate. An embodiment of the piezoelectric material of the hybrid piezoelectric-semiconductor substrate includes material selected from the group consisting of lithium niobate, lithium tantalate, aluminum nitride, alloyed aluminum nitride, doped aluminum nitride, lead zirconate titanate, and lead magnesium niobate-lead titanate. An embodiment of the semiconductor material of the hybrid piezoelectric-semiconductor substrate includes material selected from the group consisting of silicon, germanium, III-V semiconductors, diamond, silicon carbide, graphene, and molybdenum disulfide.

In an embodiment of the scheme, each of the one or more individual delay lines includes a distinct length. In an embodiment, the distinct length for each of the one or more individual delay lines is between one micron and ten millimeters.

The novel method for replicating an interference at a wireless receiver includes a step of providing an estimate of the interference at an origin to an array of acoustic delay lines. Each acoustic delay line includes a different amount of insertion delay and being formed on a composite piezoelectric semiconductor substrate. The method includes a step of individually providing a direct current voltage to each of the acoustic delay lines, thereby forming an electric field within a portion of each of the acoustic delay lines. The method includes a step of controlling and tuning a value of each of the direct current voltages until a combined output of the acoustic delay lines matches the interference arriving at a receiver. In an embodiment, the method includes a step of replicating, via the array of acoustic delay lines, the interference at a receiver chain by combining weighted and delayed copies of the interference at a transmitter chain.

In an embodiment, each acoustic delay line includes a first transducer, a propagation delay section, a second transducer, and a plurality of electrodes. An embodiment of the method includes the steps of: converting, via the first transducer, each of a plurality of incoming electromagnetic radio frequency signals into a mechanical/acoustic signal via piezoelectricity; delaying, via the propagation delay section, each mechanical/acoustic signal as each signal propagates therethrough; inducing, via the plurality of electrodes, the electric field within a portion of at least one of the individual acoustic delay lines, thereby tuning an amplitude and a phase of the mechanical/acoustic signal; and converting, via the second transducer, each mechanical/acoustic signal back into a transmitted electrical domain signal.

In an embodiment, the array of acoustic delay lines is electrically coupled to an acoustoelectric coupler. The acoustoelectric coupler includes at least one input transducer, a coupling section, at least two output transducers, and a plurality of electrodes. In an embodiment, the method includes the steps of: converting, via the at least one input transducer, each of a plurality of incoming electromagnetic radio frequency signals into a mechanical/acoustic signal via piezoelectricity; directing, via the coupling section, a propagation of a portion of each mechanical/acoustic signal therethrough; inducing, via the plurality of electrodes, a lateral and/or vertical electric field within a portion of a propagation path of each mechanical/acoustic signal; and converting, via the at least two output transducers, each directed mechanical/acoustic signal into a transmitted electrical domain signal.

In an embodiment, the array of acoustic delay lines is electrically coupled to an acoustoelectric circulator that includes at least three transducers, a propagation section, and a plurality of electrodes. An embodiment of the method includes the steps of: converting, via the at least one of the at least three transducers, each of a plurality of incoming electromagnetic radio frequency signals into a mechanical/acoustic signal via piezoelectricity; propagating, via the propagation section that is in between each of the at least three transducers, a nonreciprocal propagation path of each mechanical/acoustic signal therethrough by inducing, via the plurality of electrodes, a lateral and/or vertical electric field within a portion of the propagation path of each mechanical/acoustic signal; and converting, via at least one of the at least three transducers, each of a plurality of mechanical/acoustic signals back into electromagnetic radio frequency signals via piezoelectricity.

In an embodiment, the array of acoustic delay lines is electrically coupled to an acoustoelectric circulator that includes a plurality of interconnected acoustoelectric isolators and a plurality of power dividers. Each power divider is disposed between adjacent acoustoelectric isolators. In an embodiment, the method includes a step of guiding, via each of the plurality of interconnected acoustoelectric isolators, a mechanical/acoustic signal in only a single direction.

An object of the invention is to provide an efficient self-interference cancelation scheme that provides real-time delays with tunable amplitudes of ranges up to greater than 50 dB, while maintaining a compact size and area, thereby providing an efficient cancelation scheme in the congested sub-6 GHz frequency spectrum.

These and other important objects, advantages, and features of the invention will become clear as this disclosure proceeds.

The invention accordingly comprises the features of construction, combination of elements, and arrangement of parts that will be exemplified in the disclosure set forth hereinafter and the scope of the invention will be indicated in the claims.

### BRIEF DESCRIPTION OF THE DRAWINGS

For a fuller understanding of the invention, reference should be made to the following detailed description, taken in connection with the accompanying drawings, in which:

FIG. 1 is schematic of a full-duplex radio, in accordance with an embodiment of the present invention.

FIG. 2 is a schematic of an acoustoelectric modulation/delay line assembly, in accordance with an embodiment of the present invention.

FIG. 3 is a schematic of embodiments of acoustoelectric waveguides, in accordance with embodiments of the present invention.

FIG. 4 is a schematic of a full-duplex radio having an acoustoelectric modulation/delay line assembly for self-interference cancelation, in accordance with an embodiment of the present invention.

FIG. 5A is a schematic of an acoustoelectric coupler, in accordance with an embodiment of the present invention.

FIG. 5B is a schematic of an acoustoelectric coupler, in accordance with an embodiment of the present invention.

FIG. 5C is a schematic of an acoustoelectric coupler, in accordance with an embodiment of the present invention.

FIG. 6A is a schematic of an acoustoelectric circulator, in accordance with an embodiment of the present invention.

FIG. 6B is a schematic of an acoustoelectric circulator, in accordance with an embodiment of the present invention.

FIG. 7 is a graphical representation of the transmission response of a typical acoustoelectric waveguide in the frequency domain showing the effect of amplitude modulation by applying a control voltage laterally, in accordance with an embodiment of the present invention.

FIG. 8A is a schematic of interference cancelation using an acoustoelectric modulation/delay line assembly where the interference is generated by nearby wireless module(s), in accordance with an embodiment of the present invention.

FIG. 8B is a schematic of interference cancelation using acoustoelectric modulation/delay line assembly where the interference is generated by a shared antenna for a transmitted (Tx) and a receiver (Rx), in accordance with an embodiment of the present invention.

FIG. 9A is a schematic of interference cancelation scheme using acoustoelectric modulation/delay line assembly in a full-duplex radio, in accordance with an embodiment of the present invention.

FIG. 9B is a schematic of a prior art interference cancelation scheme in a full-duplex radio.

### DETAILED DESCRIPTION OF THE INVENTION

In the following detailed description of the preferred embodiments, reference is made to the accompanying drawings, which form a part thereof, and within which are shown by way of illustration specific embodiments by which the invention may be practiced. It is to be understood that other embodiments may be utilized and structural changes may be made without departing from the scope of the invention.

Reference in the specification to “one embodiment,” “preferred embodiment,” “an embodiment,” “some embodiments,” or “embodiments” means that a particular feature, structure, characteristic, or function described in connection with the embodiment is included in at least one embodiment of the disclosure and may be in more than one embodiment. The appearances of the phrases “in one embodiment,” “in an embodiment,” “in embodiments,” “in alternative embodiments,” “in an alternative embodiment,” “in certain embodiments, or “in some embodiments” in various places in the specification are not necessarily all referring to the same embodiment or embodiments. The terms “include,” “including,” “comprise,” and “comprising” shall be understood to be open terms and any lists that follow are examples and not meant to be limited to the listed items.

As used in this specification and the appended claims, the singular forms “a,” “an,” and “the” include plural referents unless the content clearly dictates otherwise. As used in this specification and the appended claims, the term “or” is generally employed in its sense including “and/or” unless the context clearly dictates otherwise.

All numerical designations, such as measurements, efficacies, physical characteristics, forces, and other designations, including ranges, are approximations which are varied up or down by increments of 1.0 or 0.1, as appropriate. It is to be understood, even if it is not always explicitly stated that all numerical designations are preceded by the term “about.” As used herein, “about” or “approximately” refers to being within an acceptable error range for the particular value as determined by one of ordinary skill in the art, which will depend in part on how the value is measured or determined. As used herein, the term “about” refers to ±10% of the numerical; it should be understood that a numerical including an associated range with a lower boundary of greater than zero must be a non-zero numerical, and the term “about” should be understood to include only non-zero values in such scenarios.

Acoustoelectric (AE) devices with very strong energy coupling between mechanical waves and charge carriers (electrons) have been demonstrated in hybrid piezoelectric-semiconductor substrates, such as lithium niobate-on-silicon. Other non-limiting examples of piezoelectric materials include lithium tantalate, III-V compounds such as aluminum nitride (or alloyed/doped aluminum nitride), lead zirconate titanate (PZT) family materials, and lead magnesium niobate-lead titanate (PMN-PT) family materials; similarly, non-limiting examples of semiconductor materials include germanium, silicon carbide, diamond, III-V semiconductors, and two-dimensional materials (such as graphene, molybdenum disulfide (MoS₂), and indium selenide (InSe)). These AE devices enable large real-time delays with tunable amplitude (larger than 50 dB range) monolithically realized in a millimeter to sub-millimeter range footprint, therefore providing a miniaturized solution for interference cancelation. Accordingly, the present invention includes systems and devices for a self-interference cancelation scheme that allows for large numbers of delays while maintaining a small size and area. The main components of this scheme include AE delay line arrays (for re-constructing the interference to be subtracted); AE circulators (for providing isolation between the transmitter-to-antenna and antenna-to-receiver paths for the case of a radio with shared-antenna for transmitting/receiving); and AE couplers (for tapping the signal from the transmit chain to the delay lines). Together, a fully micro-acoustic interference cancelation module is realized in thin-film piezoelectric-semiconductor heterostructures, which are usable in cellular communication devices, base stations, wireless communication modules (such as those under the trade name Wi-Fi™), and similar transmission/reception systems. While the implementation of this module entirely in the micro-acoustic domain includes each of the AE delay line array, the AE circulator, and the AE coupler, it should be appreciated that embodiments of the scheme can include an independent use of each component used in combination with other technologies to form a hybrid self-interference cancelation scheme.

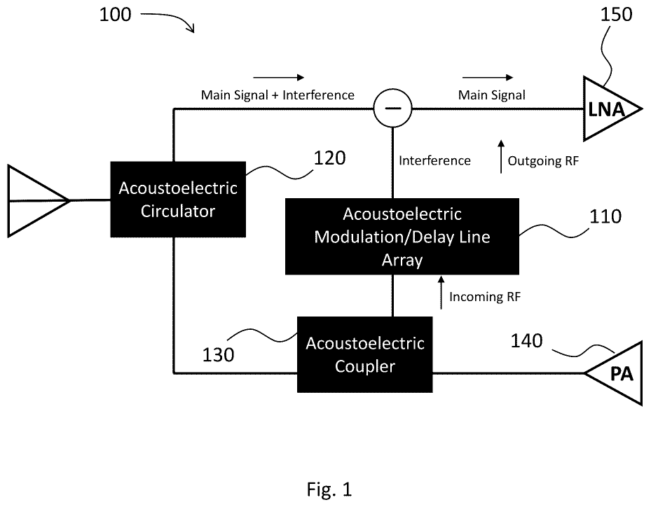

As shown in FIG. 1, an embodiment of self-interference cancelation scheme 100 includes AE delay line array 110, AE circulator 120, and AE coupler 130. AE coupler 130 taps a transmitted signal for AE modulation delay line array 110. Array 110 replicates interference by combining weighted and delayed signals and subsequently subtracts the combined signals from received signals which contain both a main signal (data) and the interference (noise), such that the main signal (and not the interference) is mainly passed to the next stage (such as a low noise amplifier). AE circulator 120 further enhances cancelation through the directional nature of the acoustoelectric phenomenon. Embodiments of scheme 100 (such as that shown in FIG. 1) include one or more of power amplifiers (PA) 140 and/or low noise amplifiers (LNA) 150 being made of transistors; however, it should be appreciated that embodiments of PA 140 and/or LNA 150 can be realized using active micro-acoustic platform or traveling wave amplifiers.

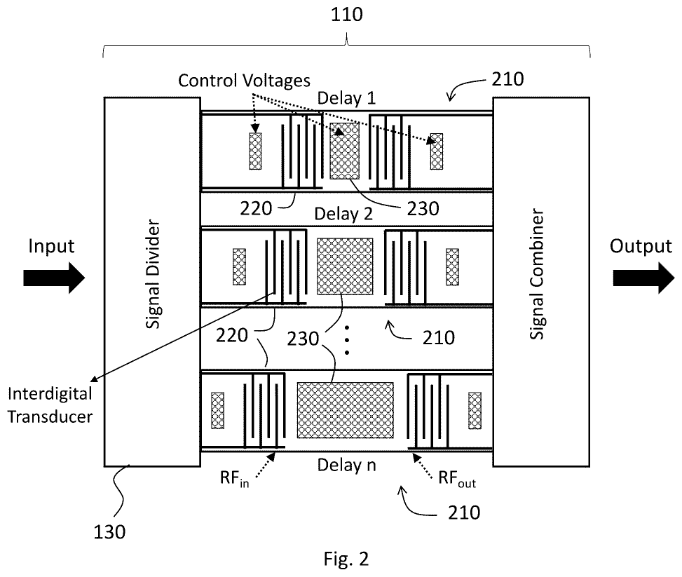

By forming an array 110 of AE delay lines, each having a distinct length (e.g., between one micron and ten millimeters), which yields real-time delays ranging from picoseconds to microseconds, and tuning one or more DC sources that are individually controlled and applied individually to the delay lines, the amplitude and phase of each of the delayed copies of the original signal can be tuned via the phonon-electron gain/loss in a way that their combination would closely replicate the interference. Within array 110, an individual AE delay line (also referred to as acoustic delay line or waveguide 210), which is micromachined on a piezoelectric-semiconductor platform, comprises one or more transducers 220 (shown in FIG. 2 as interdigital transducers made of metal, as a non-limiting case) to convert the incoming electromagnetic radio frequency (RF) signal into a mechanical/acoustic signal (via piezoelectricity, in which the piezoelectric material of a piezoelectric-semiconductor substrate ensures that the RF signal is efficiently transduced into the mechanical/acoustic domain, thereby generating traveling acoustic waves which interact with electrons within waveguide 210, and the properties of electrons, controlled by a DC signal, would control the properties of traveling acoustic waves). In embodiments, an individual AE delay line also includes propagation delay section 230 which is designed to give the desired time delay as the acoustic wave propagate through; and another transducer 220 to convert the acoustic signal back into the electrical domain. The small size of individual delay lines within array 110 allows for having many distinct time delays which increases the replication accuracy of the interference. By tapping from the same delay line multiple times at different locations, array 110 provides multiple delays of the signal with a lower number of required waveguides, and the overall size of scheme 100 can be further reduced. FIG. 2 depicts an embodiment of delay line array 110 including electrical contacts used for constructing the interference. The original signal enters through the signal divider (e.g., AE coupler 130) and is extracted from the signal combiner.

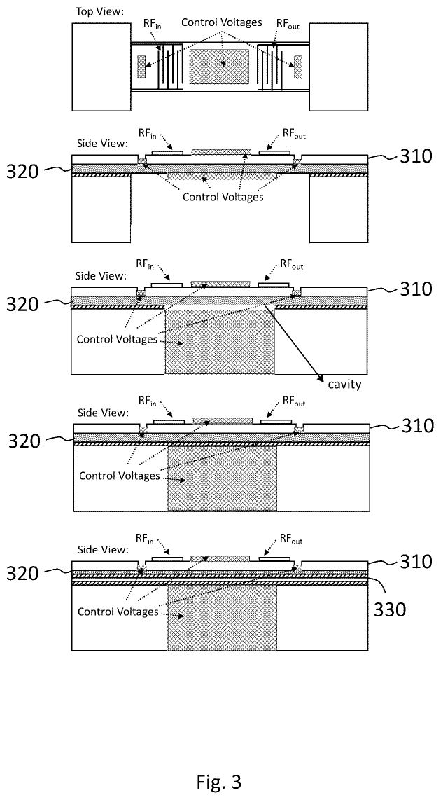

Referring now to FIG. 3, in certain embodiments, digitally controllable voltages/or electric fields can be either applied laterally across semiconductor layer 320, causing carrier velocity modulation; vertically through piezoelectric layer 310, causing carrier density modulation; or a combination of lateral and vertical applications. The control voltages result in a change of the signal properties, such as amplitude and phase. The main body of the delay line can be suspended or mounted on a substrate with or without having distributed Bragg reflectors 330 for better acoustic energy confinement.

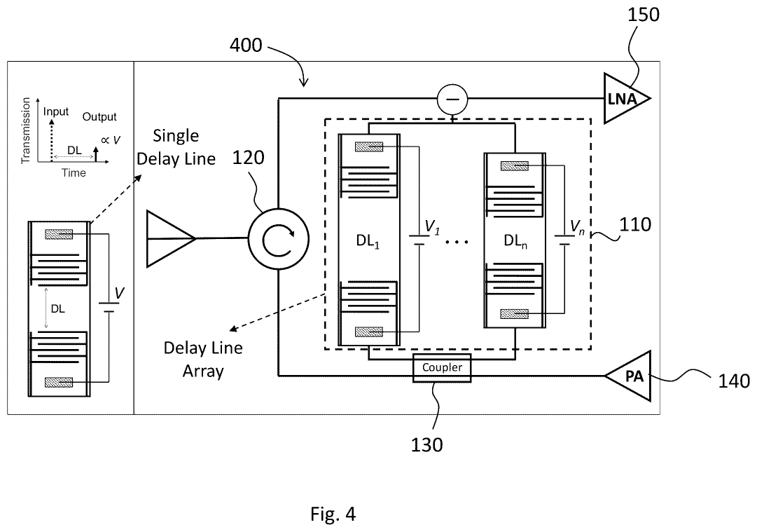

The placement of the one or more AE delay line arrays 110 within a full-duplex radio front-end 400 is shown in FIG. 4. The signal in the transmit chain is passed through a coupler (which may be implemented in the AE platform, i.e., via AE coupler 130) to be coupled into the one or more AE delay line arrays 110. Each delay line having a unique length (the separation distance between the input and output RF ports) generates a delayed version of the signal, which can be further tuned in amplitude and/or phase via the separate voltages that are applied laterally and/or vertically with respect to the wave propagation direction. The laterally-applied voltage changes the charge carrier velocity, and the vertically-applied voltage changes the carrier concentration; either change results in a change of the amplitude and phase of the signal, obviating the need for any additional attenuators and phase shifters.

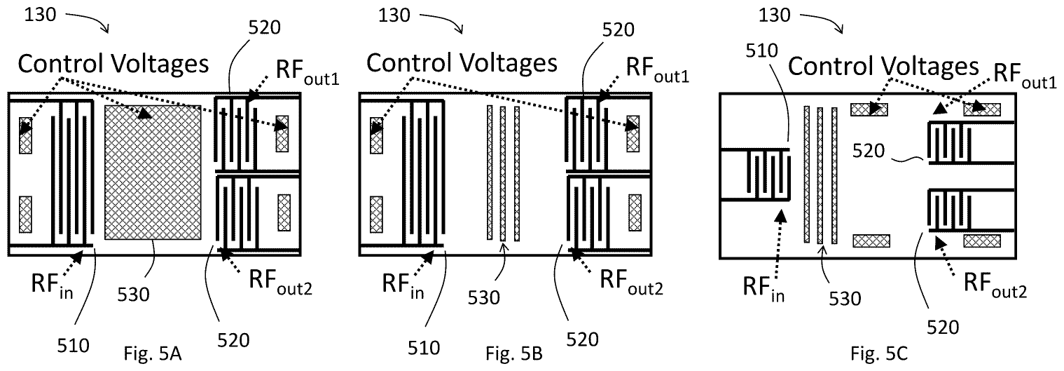

Referring to FIGS. 5A-5C, embodiments of scheme 100 include AE coupler 130 in the form of a piezoelectric-semiconductor waveguide with at least one input port 510 and at least two output ports 520. AE coupler 130 splits (into equal parts or into unequal parts) the input signal between the at least two output ports 520. The splitting is achieved by using separate bias voltages (lateral and/or vertical) to guide and amplitude-modulate acoustic waves into desired output ports 520, which can be further enhanced by using coupling structures, such as one or more microstrip lines (multistrip coupler) 530, within the waveguide. As such, each of the at least two output ports 520 receives a signal from at least one input port 510, the amplitude of which is controlled by a DC source.

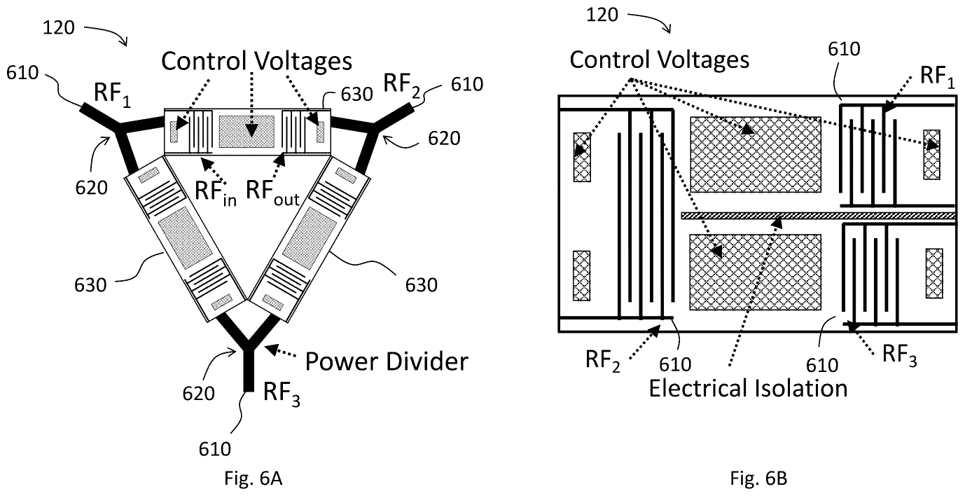

Referring to FIGS. 6A-6B, embodiments of scheme 100 include AE circulator 120 in the form of a piezoelectric-semiconductor waveguide with a plurality of ports 610 (e.g., in an embodiment, the waveguide includes at least three ports), where separate bias voltages (lateral and/or vertical) are used to guide and amplitude-modulate acoustic waves into only the desired ports. For example, as shown in FIG. 6B, the port RF₁ is connected to the transmit chain of the RF front-end; the port RF₂ is connected to the shared antenna; and the port RF₃ is connected to the receive chain of the RF front-end. The bias voltages are controlled, such that the RF signal transduced into the acoustic wave can only propagate from RF₁ to RF₂ and from RF₂ to RF₃. In this embodiment, nothing propagates in the opposite direction (i.e., from RF₂ to RF₁ or from RF₃ to RF₂) or between the RF₁ port and the RF₃ port (in either direction). It should be appreciated that different orientations of RF₁, RF₂ and RF₃ ports are contemplated herein, and that additional or fewer ports can be used in different embodiments of scheme 100. In some embodiments, as shown in FIG. 6A, a hybrid electromagnetic and acoustoelectric scheme is used where a plurality of AE isolators 630 (i.e., AE waveguides which guide signals in only a single direction) are interconnected in, for example, a delta topology using power dividers 620 in between the AE isolators 630.

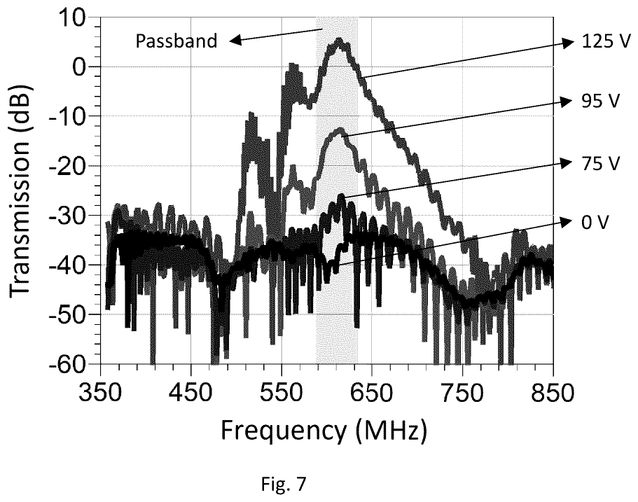

Turning to FIG. 7, an embodiment of a typical transmission response of an individual AE delay line made of lithium niobate on silicon is shown for different values of a control voltage applied laterally to the silicon layer and in parallel with the acoustic wave propagation direction. Increasing the control voltage from 0 V to 125 V changes the insertion gain of the transmitted signal from approximately −40 dB to approximately +6 dB, therefore allowing for an amplitude modulation of greater than approximately 40 dB.

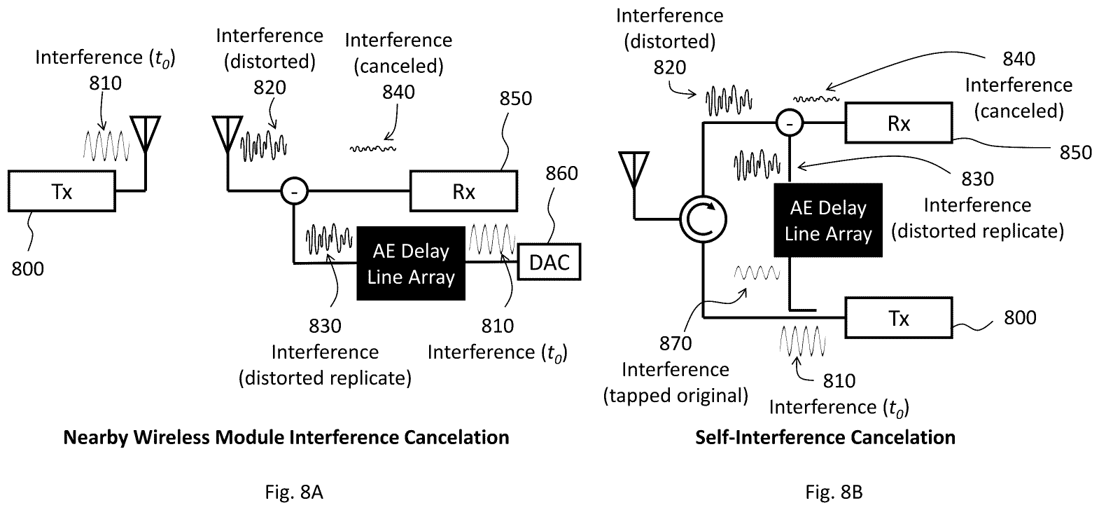

Referring to FIGS. 8A-8B, embodiments of the interference cancelation scheme are configured to reduce and/or eliminate adjacent channel or adjacent module interference with scheme 100. Specifically, as shown in FIGS. 8A-8B, embodiments for interference cancelation schemes are depicted in scenarios with nearby wireless transmitting modules and in scenarios with shared antenna for transmitting and receiving wireless signals. In both scenarios, the interference generated by the transmitter (Tx) 800 prior to distortion, labeled Interference (t₀) 810, is fed to the AE modulation/delay line array to replicate the received interference, labeled Interference (distorted) 820, and create the copy of Interference (distorted) 820, labeled Interference (distorted replicate) 830. As such, the interference cancelation schemes subsequently destructively combine Interference (distorted) 820 and Interference (distorted replicate) 830 and eliminate Interference (distorted) 820 in the receiving chain to receiver (Rx) 850, shown as Interference (canceled) 840. Embodiments of the scheme, as shown in FIGS. 8A and 8B respectively, use a digital to analog converter (DAC) 860 and an Interference (tapped original) 870 for providing Interference (t) 810 to AE modulation/delay line array 110.

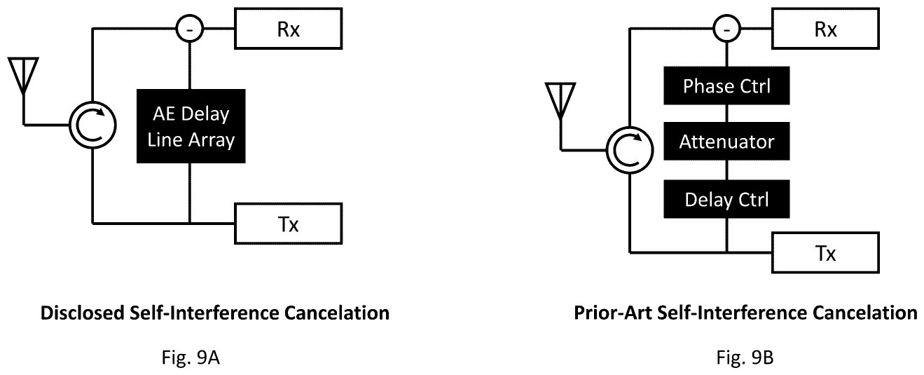

Turning to FIG. 9A, an embodiment of scheme 100 is compared to an embodiment of a prior art interference cancelation scheme (shown in FIG. 9B). Specifically as shown in FIG. 9B, an embodiment of a full-duplex radio interference cancelation scheme is depicted that includes separate modules for delay control, attenuation, and/or phase shift control. As shown in FIG. 9A, an embodiment of scheme 100 instead includes the AE modulation/delay lines that independently provide the functionalities of more than one of these modules, thereby providing large numbers of delays while maintaining a small size and area.

The advantages set forth above, and those made apparent from the foregoing description, are efficiently attained. Since certain changes may be made in the above construction without departing from the scope of the invention, it is intended that all matters contained in the foregoing description or shown in the accompanying drawings shall be interpreted as illustrative and not in a limiting sense.

It is also to be understood that the following claims are intended to cover all of the generic and specific features of the invention herein described, and all statements of the scope of the invention that, as a matter of language, might be said to fall therebetween.

What is claimed is:

1. A self-interference cancelation scheme comprising:
an acoustoelectric delay line array configured to receive each of a plurality of incoming electromagnetic radio frequency signals, the acoustoelectric delay line array including one or more individual delay lines, each of the one or more individual delay lines including:
a first transducer configured to convert each of the plurality of incoming electromagnetic radio frequency signals into a mechanical/acoustic signal via piezoelectricity;
a propagation delay section configured to provide a time delay as each mechanical/acoustic signal propagates therethrough;
a second transducer configured to convert each mechanical/acoustic signal back into a transmitted electrical domain signal; and
a plurality of electrodes configured to induce a lateral and/or vertical electric field within a portion of at least one of the individual delay lines, such that an amplitude and a phase of the mechanical/acoustic signal is tuned,
wherein the acoustoelectric delay line array replicates an interfering signal at a receiver chain by combining weighted and delayed copies of an interfering signal at a transmitter chain.

2. The self-interference cancelation scheme of claim 1, further comprising an acoustoelectric coupler electrically coupled to the acoustoelectric delay line array, the acoustoelectric coupler comprising:
at least one input transducer configured to convert each of the plurality of incoming electromagnetic radio frequency signals into a mechanical/acoustic signal via piezoelectricity;
a coupling section configured to direct a propagation of a portion of each mechanical/acoustic signal therethrough;
at least two output transducers, each output transducer configured to convert each directed mechanical/acoustic signal into a transmitted electrical domain signal; and
a plurality of electrodes configured to induce a lateral and/or vertical electric field within a portion of a propagation path of each mechanical/acoustic signal.

3. The self-interference cancelation scheme of claim 2, wherein the acoustoelectric coupler is configured to initially receive each of the plurality of incoming electromagnetic radio frequency signals and transmit a portion of each of the plurality of incoming electromagnetic radio frequency signals to the acoustoelectric delay line array.

4. The self-interference cancelation scheme of claim 2, wherein the acoustoelectric coupler further comprises one or more multistrip couplers.

5. The self-interference cancelation scheme of claim 1, further comprising an acoustoelectric circulator electrically coupled to the acoustoelectric delay line array, the acoustoelectric circulator comprising:
at least three transducers configured to convert each of the plurality of incoming electromagnetic radio frequency signals into a mechanical/acoustic signal via piezoelectricity;
a propagation section in between each of the at least three transducers, the propagation section configured for nonreciprocal propagation of each mechanical/acoustic signal therethrough; and
a plurality of electrodes configured to induce a lateral and/or vertical electric field within a portion of a propagation path of each mechanical/acoustic signal.

6. The self-interference cancelation scheme of claim 5, wherein the at least three transducers are configured to convert each of the plurality of incoming mechanical/acoustic signals into one or more outgoing electromagnetic radio frequency signals via piezoelectricity.

7. The self-interference cancelation scheme of claim 5, wherein the acoustoelectric circulator is configured to further enhance cancelation provided by the acoustoelectric delay line array implemented in a shared-antenna radio.

8. The self-interference cancelation scheme of claim 1, further comprising an acoustoelectric circulator electrically coupled to the acoustoelectric delay line array, the acoustoelectric circulator comprising a plurality of interconnected acoustoelectric isolators and a plurality of power dividers, each power divider disposed between adjacent acoustoelectric isolators, wherein the plurality of interconnected acoustoelectric isolators guide signals in only a single direction.

9. The self-interference cancelation scheme of claim 8, wherein the plurality of interconnected acoustoelectric isolators are interconnected in a delta topology.

10. The self-interference cancelation scheme of claim 1, further comprising a waveguide comprised of a hybrid piezoelectric-semiconductor substrate.

11. The self-interference cancelation scheme of claim 10, wherein the piezoelectric material of the hybrid piezoelectric-semiconductor substrate is selected from the group consisting of lithium niobate, lithium tantalate, aluminum nitride, alloyed aluminum nitride, doped aluminum nitride, lead zirconate titanate, and lead magnesium niobate-lead titanate.

12. The self-interference cancelation scheme of claim 10, wherein the semiconductor material of the hybrid piezoelectric-semiconductor substrate is selected from the group consisting of silicon, germanium, III-V semiconductors, diamond, silicon carbide, graphene, and molybdenum disulfide.

13. The self-interference cancelation scheme of claim 1, wherein each of the one or more individual delay lines includes a distinct length.

14. The self-interference cancelation scheme of claim 13, wherein the distinct length for each of the one or more individual delay lines is between one micron and ten millimeters.

15. A method for replicating an interference at a wireless receiver, the method comprising the steps of:
providing an estimate of the interference at an origin to an array of acoustic delay lines, each acoustic delay line having a different amount of insertion delay and being formed on a composite piezoelectric semiconductor substrate;
individually providing a direct current voltage to each of the acoustic delay lines, thereby forming an electric field within a portion of each of the acoustic delay lines; and
controlling and tuning a value of each of the direct current voltages until a combined output of the acoustic delay lines matches the interference arriving at a receiver.

16. The method of claim 15, further comprising the step of replicating, via the array of acoustic delay lines, the interference at a receiver chain by combining weighted and delayed copies of the interference at a transmitter chain.

17. The method of claim 15, wherein each acoustic delay line comprises a first transducer, a propagation delay section, a second transducer, and a plurality of electrodes, further comprising the steps of:
converting, via the first transducer, each of a plurality of incoming electromagnetic radio frequency signals into a mechanical/acoustic signal via piezoelectricity;
delaying, via the propagation delay section, each mechanical/acoustic signal as each signal propagates therethrough;
inducing, via the plurality of electrodes, the electric field within a portion of at least one of the individual acoustic delay lines, thereby tuning an amplitude and a phase of each mechanical/acoustic signal; and
converting, via the second transducer, each mechanical/acoustic signal back into a transmitted electrical domain signal.

18. The method of claim 15, wherein the array of acoustic delay lines is electrically coupled to an acoustoelectric coupler, the acoustoelectric coupler comprising at least one input transducer, a coupling section, at least two output transducers, and a plurality of electrodes, further comprising the steps of:
converting, via the at least one input transducer, each of a plurality of incoming electromagnetic radio frequency signals into a mechanical/acoustic signal via piezoelectricity;
directing, via the coupling section, a propagation of a portion of each mechanical/acoustic signal therethrough;
inducing, via the plurality of electrodes, a lateral and/or vertical electric field within a portion of a propagation path of each mechanical/acoustic signal; and
converting, via the at least two output transducers, each directed mechanical/acoustic signal into a transmitted electrical domain signal.

19. The method of claim 15, wherein the array of acoustic delay lines is electrically coupled to an acoustoelectric circulator, the acoustoelectric circulator comprising at least three transducers, a propagation section, and a plurality of electrodes, further comprising the steps of:
converting, via at least one of the at least three transducers, each of a plurality of incoming electromagnetic radio frequency signals into a mechanical/acoustic signal via piezoelectricity;
propagating, via the propagation section that is in between each of the at least three transducers, a nonreciprocal propagation path of each mechanical/acoustic signal therethrough by inducing, via the plurality of electrodes, a lateral and/or vertical electric field within a portion of the propagation path of each mechanical/acoustic signal; and
converting, via at least one of the at least three transducers, each of a plurality of mechanical/acoustic signals back into electromagnetic radio frequency signals via piezoelectricity.

20. The method of claim 15, wherein the array of acoustic delay lines is electrically coupled to an acoustoelectric circulator, the acoustoelectric circulator comprising a plurality of interconnected acoustoelectric isolators and a plurality of power dividers, each power divider disposed between adjacent acoustoelectric isolators, further comprising the step of guiding, via each of the plurality of interconnected acoustoelectric isolators, a mechanical/acoustic signal in only a single direction.
